(19) United States
(12) Patent Application Publication
(10) Pub. No.: US 2011/0057540 A1
(43) Pub. Date: Mar. 10, 2011

(54) SAW TRANSPONDER FOR SENSING PRESSURE

(75) Inventors: Bum Kyoo Choi, Seoul (KR); Du-Hwan Choi, Suwon (KR)

(73) Assignee: MDT CO. LTD., Sungnam, Gyeonggi-do (KR)

(21) Appl. No.: 12/298,767

(22) PCT Filed: Apr. 27, 2007
(86) PCT No.: PCT/KR07/02095

§ 371 Date: Nov. 11, 2010

(30) Foreign Application Priority Data
Apr. 28, 2006 (KR) 10-2006-0038848

(51) Int. Cl. H03H 9/64

(52) U.S. Cl. 310/313 B

(57) ABSTRACT

The present invention relates to a surface acoustic wave (SAW) transponder for sensing pressure, and more particularly, to a SAW transponder for sensing pressure, in which a pressure sensor is connected to a SAW transponder receiving an applied radio frequency (RF) signal to generate a surface acoustic wave (SAW) and which can detect a change of a pressure through an amplitude change of a SAW. According to the present invention, a structure of a surface acoustic wave (SAW) transponder for sensing pressure is improved, and thus the change of an external pressure can be effectively detected. In addition, since the variations of the external pressure and the pressure sensor have a linear relationship with each other, the change of the external can be easily and quantitatively detected, and an external transmit/receive device can easily analyze a pressure signal.

### TECHNICAL FIELD

The present invention relates to a surface acoustic wave (SAW) transponder for sensing pressure, and more particularly, to a SAW transponder for sensing pressure, in which a pressure sensor is connected to a SAW transponder receiving an applied radio frequency (RF) signal to generate a surface acoustic wave (SAW) and which can detect a change of a pressure through an amplitude change of a SAW.

### BACKGROUND ART

FIG. 1 is a schematic view of a structure of a conventional surface acoustic wave (SAW) transponder using a surface acoustic wave (SAW).

The SAW transponder has a structure in which a plurality of inter digital transducer (IDT) metal electrodes are arranged on a piezoelectric substrate 1, which is formed of a material such as LiNbO₃ having piezoelectricity, wherein the IDT metal electrodes are arranged along a propagating direction of SAW.

When an external transmit/receive device (not shown) wirelessly transmits an interrogation pulse signal, which is a radio frequency (RF) signal, the pulse signal is applied to a transmit/receive IDT 2 through an antenna 3 of the SAW transponder. When the pulse signal having a high frequency is incident to the transmit/receive IDT 2, the SAW is generated by the piezoelectric substrate 1.

The SAW generated from the transmit/receive IDT 2 proceeds to a detect IDT 4. A part of the SAW continually proceeds in a proceeding direction, and simultaneously a reflective wave having an opposite direction to the proceeding direction are generated. The generated reflective wave is applied to the transmit/receive IDT 2. The transmit/receive IDT 2 converts the applied reflective wave to a pulse signal (wireless response signal) which is an electric signal, and then wirelessly transmits the reflective wave to the external transmit/receive device through the antenna 3. At this time, when a pressure sensor 5 of which impedance is varied according to the variance of the pressure is connected to the detect IDT 4, the amplitude of the reflective wave is changed according to the variance of the impedance of the pressure sensor 5. The external transmit/receive device can detect a pressure of a place on which the pressure sensor 5 is equipped by analyzing the shape of the reflective wave.

The SAW transponder for sensing pressure does not require an additional power supply. The SAW transponder for sensing pressure can supply a power through a RF signal applied to the transmit/receive IDT 2, and can wirelessly transmit a detected pressure signal to the external transmit/receive device. Due to such advantages, the SAW transponder for sensing pressure is used in a tire pressure monitoring system (TPMS) detecting a pressure of the inside of a tire of a vehicle.

To use the SAW transponder for sensing pressure in the TPMS, there is a need for a pressure sensor that can sensitively and quantitatively detect the change of an external to pressure. In addition, there is a need for a SAW transponder for sensing pressure in which an impedance of the pressure sensor is linearly dependent to the change of the external pressure and a pressure signal can be easily analyzed by an external device.

### DESCRIPTION OF THE DRAWINGS

FIG. 1 is a schematic view of a structure of a conventional surface acoustic wave (SAW) transponder using a surface acoustic wave (SAW);

FIG. 2 is a schematic view illustrating a structure of a SAW transponder for sensing pressure according to an embodiment of the present invention;

FIG. 3 is a cross-sectional view of a capacitive pressure sensor of the SAW transponder for sensing pressure taken along a line of FIG. 2;

FIG. 4 is a view illustrating a lower electrode of the capacitive pressure sensor of the SAW transponder for sensing pressure of FIG. 2;

FIGS. 5 through 8 are views illustrating a method of manufacturing the SAW transponder for sensing pressure of FIG. 2;

FIGS. 9 and 10 are views illustrating a pressure change of the SAW transponder for sensing pressure of FIG. 2; and

FIG. 11 is a view illustrating an RF pulse waveform of a state illustrated in FIG. 3; and

FIGS. 12 and 13 are views illustrating RF pulse waveforms of states that are respectively illustrated in FIGS. 9 and 10.

### EXPLANATION OF REFERENCE NUMERALS DESIGNATING THE MAJOR ELEMENTS OF THE DRAWINGS

| | |
|---|---|
| 100; SAW transponder for sensing | 10; transmit/receive IDT |
| pressure | |
| 20; detect IDT | 30; capacitive pressure sensor |
| 40; antenna | 50; detect IDT |
| 6; piezoelectric substrate | 31; substrate |
| 32; lower electrode | 33; dielectric layer |
| 34; upper electrode | 341; supporting portion |
| 342; electrode portion | |

### DETAILED DESCRIPTION OF THE INVENTION

### Technical Problem

The present invention provides a surface acoustic wave (SAW) transponder for sensing pressure, that can effectively detect an external pressure since the electric capacity varies according to the change of an external pressure, wherein the variations of the external pressure and the electric capacity have a linear relationship with each other.

### Technical Solution

According to an aspect of the present invention, there is provided a surface acoustic wave (SAW) transponder for sensing pressure including a transmit/receive inter digital transducer (IDT) receiving an applied signal to generate a surface acoustic wave (SAW) and receiving a SAW to generate a radio frequency (RF) signal, a detect IDT reflecting the SAW transmitted from the transmit/receive IDT to return the SAW to the transmit/receive IDT, and a capacitive pressure sensor which is electrically connected to the detect IDT to modulate an amplitude of the SAW reflected by the detect IDT, wherein electric capacity of the capacitive pressure of the capacitive pressure sensor is changed according to a surrounding pressure, wherein the capacitive pressure sensor includes a substrate, a conductive lower electrode formed on the substrate to cover a predetermined area of the substrate, a dielectric layer formed on the substrate to cover the lower electrode, and an upper electrode comprising a ring-type supporting portion disposed on the substrate, and an electrode portion that is supported by the supporting portion, that hermetically seals a space above the lower electrode, which is surrounded by the supporting portion, and that is formed to contact the dielectric layer while being elastically deformed according to an increase of a pressure applied from an upper part, wherein electric capacity of the upper electrode and the lower electrode is changed according to an area of the electrode portion, which contacts the dielectric layer.

### ADVANTAGEOUS EFFECTS

According to the present invention, a structure of a surface acoustic wave (SAW) transponder for sensing pressure is improved, and thus the change of an external pressure can be effectively detected.

In addition, since the variations of the external pressure and the pressure sensor have a linear relationship with each other, the change of the external can be easily and quantitatively detected, and an external transmit/receive device can easily analyze a pressure signal.

### BEST MODE

Preferred embodiments of the present invention will now be described with reference to the attached drawings.

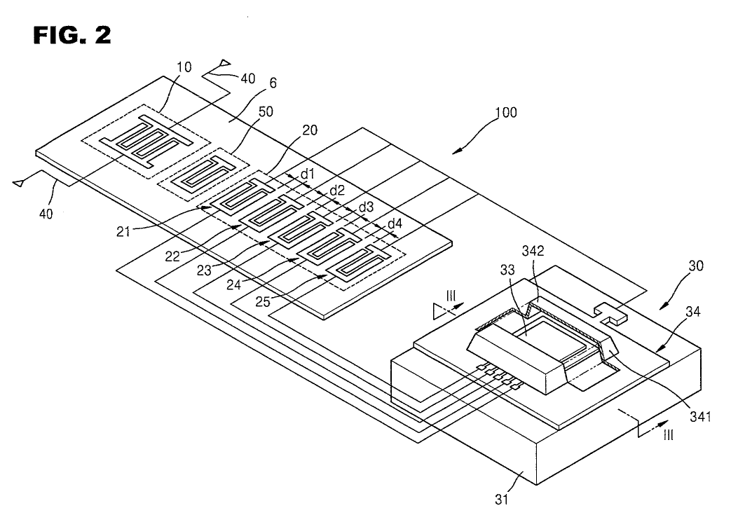

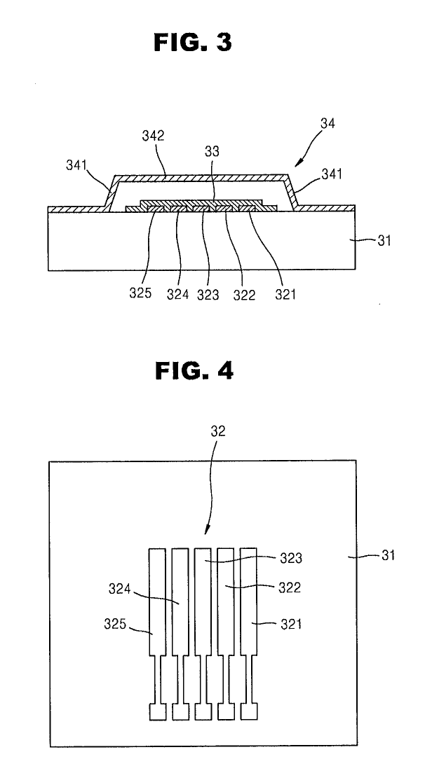

FIG. 2 is a schematic view illustrating a structure of a surface acoustic wave (SAW) transponder for sensing pressure 100 according to an embodiment of the present invention. FIG. 3 is a cross-sectional view of a capacitive pressure sensor 30 of the SAW transponder 100 for sensing pressure taken along a line III-III of FIG. 2. FIG. 4 is a view illustrating a lower electrode of the capacitive pressure sensor 30 of the SAW transponder for sensing pressure 100 of FIG. 2.

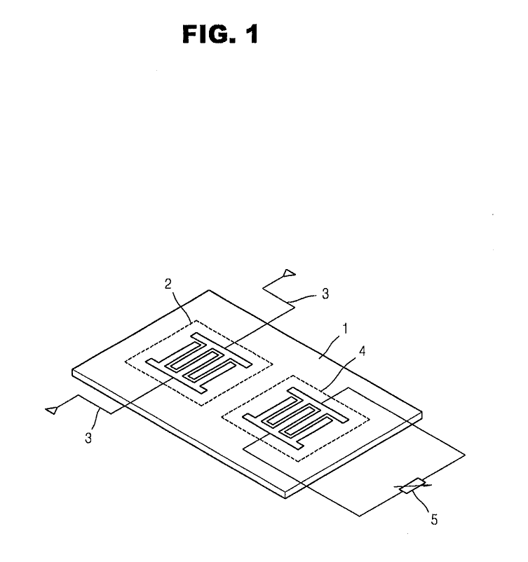

Referring to FIGS. 1 through 3, the SAW transponder for sensing pressure 100 includes a transmit/receive inter digital transducer (IDT) 10, a detect IDT 20, a standard IDT 50, a capacitive pressure sensor 30 and an antenna 40.

The transmit/receive IDT 10, the detect IDT 20 and the standard IDT 50 are each an IDT formed on a piezoelectric substrate 6 having piezoelectricity, such as LiNbO₃. The IDT applies an electric signal or a radio frequency (RF) signal to a plurality of metal electrodes parallel to one another and generates a surface acoustic wave (SAW). IDTs are well known to one of ordinary skill in the field in which SAW is used, and thus its detailed descriptions will be omitted.

Since the transmit/receive IDT 10 is connected to the antenna 40, RF signals received from the outside through the antenna 40 are converted into SAW, or SAW applied from the standard IDT 50 or the detect IDT 20 is converted into RF signals so that converted signals may be transmitted to the outside through the antenna 40.

The detect IDT 20 is formed on the piezoelectric substrate 6, which is on a path along which SAW generated by the transmit/receive IDT 10 is transmitted, and are spaced from the transmit/receive IDT 10 by a predetermined distance. Accordingly, the detect IDT 20 reflects the SAW transmitted from the transmit/receive IDT 10 to return the SAW to the transmit/receive IDT 10. The detect IDT 20 includes a plurality of detect IDT elements 21, 22, 23, 24 and 25. The detect IDT elements 21, 22, 23, 24 and 25 are arranged so that intervals d1, d2, d3 and d4 between adjacent ones of the detect IDT elements 21, 22, 23, 24 and 25 may be the same according to the amplitude of the SAW in order to reduce loss of the SAW. The detect IDT 20 includes five detect IDT elements 21, 22, 23, 24 and 25, as illustrated in FIG. 2. Since the detect IDT 20 is electrically connected to the capacitive pressure sensor 30, the detect IDT 120 modulates the is amplitude of the SAW to reflect the SAW according to electric capacity of the capacitive pressure sensor 30.

Since the standard IDT 50 is also formed on the piezoelectric substrate 6, and is disposed between the transmit/receive IDT 10 and the detect IDT 20, the standard IDT 50 reflects a part of the SAW generated from the transmit/receive IDT 10 to return the part of the SAW to the transmit/receive IDT 10, and transmits the other parts of the SAW to the detect IDT 20. Since an external impedance such as the capacitive pressure sensor 30 is not connected to the standard IDT 50, the SAW reflected by the standard IDT 50 is a standard for determining the amplitude change of SAW reflected by the detect IDT 200.

The capacitive pressure sensor 30 includes a substrate 31, a lower electrode 32, a dielectric layer 33 and an upper electrode 34.

The substrate 31 is formed of an insulating material, that is, pyrex glass.

The lower electrode 32 is configured in a structure in which a conductive metal (e.g., aluminum or copper) covers a predetermined area of an upper surface of the substrate 10. The lower electrode 32 includes a plurality of lower electrode elements 321, 322, 323, 324 and 325 spaced apart one another. As illustrated in FIG. 4, the lower electrode 32 includes five lower electrode elements 321, 322, 323, 324 and 325. As illustrated in FIG. 2, the lower electrode elements 321, 322, 323, 324 and 325 are respectively and electrically connected to the detect IDT elements 21, 22, 23, 24 and 25.

The dielectric layer 33 is formed on the substrate 31 to cover the lower electrode 32, and is formed of a material having dielectricity. In particular, the dielectric layer 33 may be formed of SiO₂ material that is usually used in a micro electro mechanical system (MEMS) technology and is easily deposited.

The upper electrode 34 includes a supporting portion 341 and an electrode portion 342.

The supporting portion 341 is formed on an upper surface of the substrate 31, and is formed to have a square ring shape.

The electrode portion 342 is supported by the supporting portion 341, and the upper space 37 of the lower electrode 32 surrounded by the supporting portion 341 is hermetically sealed. Thus, the empty upper space 37 is formed between the dielectric layer 33 and the electrode portion 342. The electrode portion 342 is formed of a conductive material. While the electrode portion 342 is elastically deformed according to the increase of a pressure applied on the upper surface of the electrode portion 342, the electrode portion 342 is configured to contact the dielectric layer 33. The electrode portion 342 of the upper electrode 34 is formed of silicon (Si) to which boron (B) ion or phosphorus (P) ion is ion-implanted. The silicon (Si), which is a nonconducting substance, becomes conductive by ion-implantation of the boron (B) ion or the phosphorus (P) ion.

As a pressure applied to an upper surface of the electrode portion 342 increases, the electrode portion 342 is elastically deformed, and thus an area of the electrode portion 342, which contacts the dielectric layer 33, is increased. As the pressure applied to the upper surface of the electrode portion 342 decreases, the electrode portion 342 is elastically restored. Thus, when the area of the electrode portion 342, which contacts the dielectric layer 33, is decreased and the pressure becomes less and less, the electrode portion 342 stops contacting the dielectric layer 33.

As illustrated in FIG. 2, the supporting portion 341 of the upper electrode 34 is electrically connected to the detect IDT elements 21, 22, 23, 24 and 25.

Hereinafter, a method of manufacturing the capacitive pressure sensor 30 will be described in detail.

The SAW transponder for sensing pressure 100 is manufactured using a common MEMS technology.

First, the lower electrode 32 having a predetermined area is deposited on the substrate 31 formed of pyrex glass.

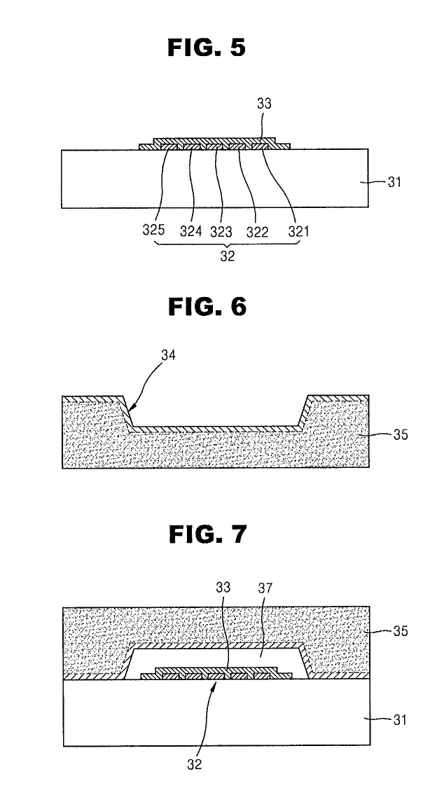

SiO₂ is deposited on the lower electrode 32 deposited on the substrate 31 to cover the lower electrode 32, and thus the dielectric layer 33 is formed to obtain a structure of FIG. 5.

As illustrated in FIG. 6, by etching an additional silicon (Si) substrate 50 in order to form the upper electrode 34, a concave shape for forming the upper space 37, which is hermetically sealed, is formed over the dielectric layer 33.

As a dotted line of FIG. 6, boron (B) ion or phosphorus (P) is ion-implanted, and thereby, permeates a predetermined thickness into the Si substrate 35, and as a result the Si substrate 35 becomes conductive.

The Si substrate 35 is reversed as illustrated in FIG. 6. The Si substrate 35 is attached onto the substrate 31 formed of pyrex glass as illustrated in FIG. 5 using an anodic bonding method to obtain a structure of FIG. 7. Using such method, the empty upper space 37 is formed between the dielectric layer 33 and the electrode portion 342 of the upper electrode 34. Meanwhile, prior to attaching the Si substrate 35 onto the substrate 31 formed of pyrex glass, a portion of each of the lower electrode elements 321, 322, 323, 324 and 325 of the lower electrode 32, which contacts the substrate 31 formed of pyrex glass, is treated to be insulated. Thus, short circuiting is prevented between the upper electrode 34 and each of the lower electrode elements 321, 322, 323, 324 and 325.

Lapping is performed onto the Si substrate 35 of the structure of FIG. 7. The Si substrate 35 is planed to a predetermined degree as illustrated in FIG. 8 to be etched. Then, only the upper electrode 34, into which boron (B) ion or phosphorus (P) ion permeates, remains. As a result, the capacitive pressure sensor 30, which is used in the SAW transponder for sensing pressure 100 of FIG. 4, is completed.

Hereinafter, the function of the SAW transponder for sensing pressure 100 will be described.

First, when an external transmit/receive device (not shown) transmits interrogation pulse signals, which are high frequency pulse signals or RF signals, to the SAW transponder for sensing pressure 100 by wireless, the interrogation pulse signals are applied to the transmit/receive IDT 10 through the antenna 40 of the SAW transponder for sensing pressure 100.

When the high frequency pulse signals are incident to the transmit/receive IDT 10, the piezoelectric substrate 6 generates the SAW.

When the SAW reach the standard IDT 50, a part of the SAW is reflected to be returned to the transmit/receive IDT 10, and the other parts of the SAW are transmitted to the detect IDT 20.

The SAW reaching the detect IDT 20 via the standard IDT 50 are sequentially reflected by the detect IDT elements 21, 22, 23, 24 and 25 to be returned to the transmit/receive IDT 10.

At this time, the detect IDT 20 modulates the amplitude of the SAW to reflect the SAW according to electric capacity of the capacitive pressure sensor 30 connected to the detect IDT 20.

The SAW, which are reflected by the standard IDT 50 and the detect IDT 20 and reach the transmit/receive IDT 10, is converted into RF signals by the transmit/receive IDT 10 to be transmitted to the external transmit/receive device via the antenna 40. Since the RF signals include RF signals of which amplitudes are modulated by the capacitive pressure sensor 30, the RF signals are analyzed by the external transmit/receive device, and thus a pressure of a place, where the capacitive pressure sensor 30 is equipped, can is be recognized. In the SAW transponder for sensing pressure 100 including the standard IDT 50, since the standard IDT 50 is not connected to an external impedance such as the capacitive pressure sensor 30, the amplitudes of the SAW is not changed. Accordingly, by comparing pulse signals reflected by the standard IDT 50 with pulse signals reflected by the detect IDT 20, the change of the pressure can be effectively recognized.

When surrounding pressure is not large, the capacitive pressure sensor 30 is in a state such that the electrode portion 342 of the upper electrode 34 and the dielectric layer 33 may not contact each other. At this time, since the electrode portion 342 of the upper electrode 34 and the dielectric layer 33 are separated from each other, and the empty upper space 37, which is an air layer, is formed between the electrode portion 342 of the upper electrode 34 and the dielectric layer 33, the capacitance between the upper electrode 34 and the lower electrode 32 has a relatively small quantity.

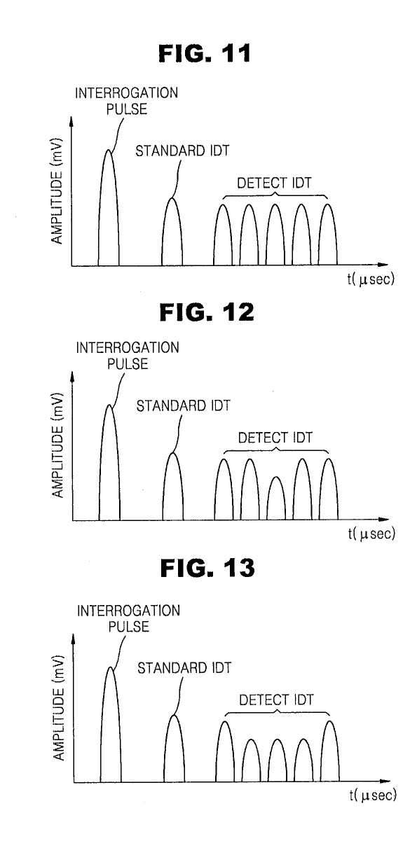

In such state, when the interrogation pulse signals are transmitted to the transmit/receive IDT 10, the pulse signals reflected by the standard IDT 50 and the detect IDT elements 21, 22, 23, 24 and 25 are not largely different in terms of amplitudes of the pulse signals, as illustrated in FIG. 11.

When the pressure of the space, where the capacitive pressure sensor 30 is equipped, increases, the electrode portion 342 of the upper electrode 34 is elastically deformed due to a pressure applied to the upper surface of the electrode portion 342, and a portion of the electrode portion 342 contacts the dielectric layer 33, as illustrated in FIG. 9. Since the dielectric layer 33 has relatively higher dielectricity than the air, the capacitance is increased between the upper electrode 34 and the lower electrode element 323 that is located on a central part of the lower electrode 32. Accordingly, impedance is changed between the lower electrode element 323 that is located on a central part of the lower electrode 32 and the upper electrode 34, and thus pulse signals can be observed as illustrated in FIG. 12. As illustrated in FIG. 12, each amplitude of the pulse signals reflected by the detect IDT element 23 connected to the lower electrode element 323 that is located on a central part of the lower electrode 32 is smaller than that of pulse signals reflected by other detect IDT elements 21, 22, 24 and 25.

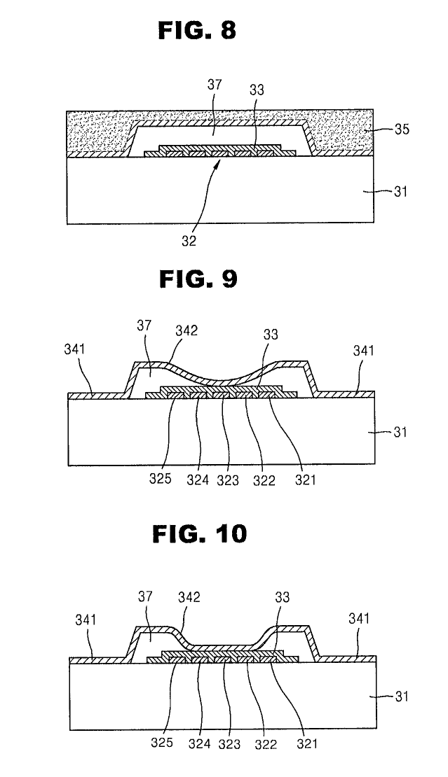

Again, when the pressure of the space, where the capacitive pressure sensor 30 is equipped, increases, the elastic deformation of the electrode portion 342 of the upper electrode 34 is increased. Then, the portion of the electrode portion 342, which contacts the dielectric layer 33, is increased as illustrated in FIG. 10. Due to the reason described is above, the capacitance is increased between the upper electrode 34 and each of the lower electrode elements 322, 323 and 324 that are the central three of the lower electrode 32. In this case, the amplitudes of pulse signals reflected by the detect IDT elements 22, 23 and 24 connected to the lower electrode elements 322, 323 and 324 that are the central three of the lower electrode 32 are smaller than of the amplitudes of pulse signals reflected by other detect IDT elements 21 and 25, as illustrated in FIG. 13.

Meanwhile, when the pressure of the space, where the capacitive pressure sensor 30 is equipped, decreases, the electrode portion 342 of the upper electrode 34 is elastically restored. Simultaneously, the portion of the electrode portion 342, which contacts the dielectric layer 33, is decreased, and thus, the amplitudes of the pulse signals transmitted from the transmit/receive IDT 10 are changed.

Since the SAW transponder for sensing pressure 100 wirelessly supplies power, an additional power supply is not required. In addition, since the SAW transponder for sensing pressure 100 wirelessly transmits and receives pulse signals, the SAW transponder for sensing pressure 100 can be effectively equipped even on a place such as the inner part of a tire, where it is difficult to equip a wired pressure sensor.

In the case where the lower electrode 32 includes the lower electrode elements 321, 322, 323, 324 and 325, since the pulse signals reflected by the detect IDT elements 21, 22, 23, 24 and 25, which are respectively connected to the lower electrode elements 321, 322, 323, 324, and 325, are separately converted, the quantitative change of an exterior pressure can be easily digitalized to be detected from the pulse signals illustrated in FIGS. 11 through 13.

In addition, compared with the case where a capacitive pressure sensor is used, in which a pressure is measured using the change of a distance between two electrodes including a dielectric layer therebetween, the SAW transponder for sensing pressure 100 can have improved sensitivity with respect to pressure due to a large variation of capacitance since the SAW transponder for sensing pressure 100 measures a pressure using a touch mode capacitive pressure sensor 30 in which a change of an area of the electrode portion 342 of the upper electrode 34, which contacts the dielectric layer 33, is employed.

### MODE OF THE INVENTION

Although the embodiment of the present invention has been described, the surface acoustic wave (SAW) transponder for sensing pressure 100 is not limited thereto.

For example, although the number (i.e. five) of the detect IDT elements 21, 22, 23, 24 and 25 is described to be the same of that of the lower electrode elements 321, 322, 323, 324 and 325, the numbers of the detect IDT elements and the lower electrode elements may be variously changed. In addition, each connection between the detect IDT elements and the lower electrode elements is not limited to a one-to-one combination.

That is, the detect IDT elements may be connected in various combinations with the lower electrode elements.

The lower electrode may include one lower electrode having a predetermined area rather than a plurality of lower electrode elements. In this case, according to an area of an electrode portion of the upper electrode, which contacts the dielectric layer, the capacitance between the upper electrode and the lower electrode is changed, and accordingly the variation of the amplitude of the pulse signal reflected by the detect IDT is increased in proportion to the change of the capacitance. Accordingly, in an external transmit/receive device, the variation of the amplitude of the pulse signal is analyzed and the pressure is recognized. In this case, since the capacitance of the pressure sensor is increased in proportion to the increase of the area of the electrode portion of the upper electrode, which contacts the dielectric layer, the changes of the pressure and the capacitance have linear relationship with each other. Accordingly, the pressure can be easily converted from the capacitance.

In addition, the SAW transponder for sensing pressure may be configured in a structure having no standard IDT. When the SAW transponder for sensing pressure does not include the standard IDT, the pulse signals reflected by the standard IDT and the detect IDT are not compared with each other. At this time, the pressure change is analyzed according to the amplitude change of the pulse signals reflected by the detect IDT, and the pressure change can be detected.

1. A SAW (surface acoustic wave) transponder for sensing pressure comprising:
a transmit/receive IDT (inter digital transducer) receiving an applied signal to generate a SAW (surface acoustic wave) and receiving a SAW to generate a RF (radio frequency) signal;
a detect IDT reflecting the SAW transmitted from the transmit/receive IDT to return the SAW to the transmit/receive IDT; and
a capacitive pressure sensor which is electrically connected to the detect IDT to modulate an amplitude of the SAW reflected by the detect IDT, wherein electric capacity of the capacitive pressure of the capacitive pressure sensor is changed according to a surrounding pressure,
wherein the capacitive pressure sensor comprises:
a substrate;
a conductive lower electrode formed on the substrate to cover a predetermined area of the substrate;
a dielectric layer formed on the substrate to cover the lower electrode; and
an upper electrode comprising a ring-type supporting portion disposed on the substrate, and an electrode portion that is supported by the supporting portion, that hermetically seals a space above the lower electrode which is surrounded by the supporting portion, and that is formed to contact the dielectric layer while being elastically deformed according to an increase of pressure applied from an upper part,
wherein electric capacity of the upper electrode and the lower electrode is changed according to an area of the electrode portion, which contacts the dielectric layer.

2. The SAW transponder of claim 1, further comprising an antenna which receives a RF signal from the outside to apply the RF signal to the transmit/receive IDT, and transmits the RF signal generated by the transmit/receive IDT to the outside.

3. The SAW transponder of claim 1, further comprising:
a standard IDT reflecting a SAW functioning as a standard which is used to determine amplitude modulation characteristic of the SAW reflected from the detect IDT.

4. The SAW transponder of claim 3, wherein the standard IDT is disposed between the transmit/receive IDT and the detect IDT.

5. The SAW transponder of claim 1, wherein the lower electrode of the capacitive pressure sensor comprises a plurality of lower electrode elements spaced apart from one another.

6. The SAW transponder of claim 5, wherein the detect IDT comprises a plurality of detect IDT elements, and
at least one of the detect IDT elements of the detect IDT and at least one of the lower electrode elements of the lower electrode are electrically connected.

7. The SAW transponder of claim 6, wherein the number of the detect IDT elements is the same as the number of the lower electrode elements, and
the detect IDT elements of the detect IDT are respectively and electrically connected to the lower electrode elements of the lower electrode.

8. The SAW transponder of claim 6, wherein intervals between adjacent detect IDT elements are the same.

9. The SAW transponder of claim 7, wherein intervals between adjacent detect IDT elements are the same.
